(19) United States
(12) Patent Application Publication
(10) Pub. No.: US 2025/0309010 A1
(43) Pub. Date: Oct. 2, 2025

(54) POWER MODULE

(71) Applicant: DAIHEN CORPORATION, Osaka-shi (JP)

(72) Inventor: Shingo KAWANO, Osaka-shi (JP)

(21) Appl. No.: 19/089,755

(22) Filed: Mar. 25, 2025

(30) Foreign Application Priority Data
Mar. 29, 2024 (JP) 2024-056991

(51) Int. Cl. H01L 23/057; H01L 23/31; H01L 23/538; H01L 25/18

(52) U.S. Cl. CPC H01L 23/057; H01L 23/538; H01L 25/18; H01L 23/3107

(57) ABSTRACT

A conductor layer formed on a front surface of an insulating substrate occasionally discharges. A power module includes an insulating substrate, a semiconductor device mounted on the insulating substrate, a casing that houses the insulating substrate together with the semiconductor device, and a sealing material that seals the semiconductor device inside the casing. On the front surface of the insulating substrate, a conductor pattern is formed, the conductor pattern including at least a conductor layer where the semiconductor device is mounted, and on a front surface of the conductor layer, the front surface of the insulating substrate, together with a periphery edge of the conductor layer, is covered by an insulating film so as to expose a mounting region where the semiconductor device is mounted.

### RELATED APPLICATIONS

The present application claims to Japanese Patent application No. JP 2024-056991, filed on Mar. 29, 2024, the entire content of which is incorporated herein by reference.

### BACKGROUND OF THE INVENTION

### 1. Field of the Invention

The present invention relates to a high voltage power module.

### 2. Description of the Related Art

As a technique of this type, a power module has been proposed that includes an insulating substrate made of ceramics, a semiconductor device mounted on the insulating substrate, a casing that houses the insulating substrate together with the semiconductor device, and a sealing material that seals the semiconductor device inside the casing (see, for example, JP 2007-12831 A). A conductor pattern including a conductor layer where the semiconductor device is mounted is formed on a front surface of the insulating substrate.

### SUMMARY OF THE INVENTION

In the power module of JP 2007-12831 A, when a periphery edge of a conductor layer is not fully covered by a sealing material or air bubbles are formed in the sealing material at the periphery edge of the conductor layer, discharge from the conductor layer occurs. Further, even with a high-insulative resin applied on a side surface of the edge of the conductor layer, when an upper edge of the conductor layer is exposed or air bubbles are formed in the applied resin, discharge from the conductor layer occasionally occurs.

The present invention has been made in view of such an issue, and provides a power module capable of suppressing discharge from a conductor layer formed on a front surface of an insulating substrate.

In view of the aforementioned issues, a power module according to the present invention is a high voltage power module including: at least one insulating substrate made of ceramics; a semiconductor device mounted on the insulating substrate; a casing that houses the insulating substrate together with the semiconductor device; and a sealing material that seals the semiconductor device inside the casing, in which on a front surface of the insulating substrate, a conductor pattern is formed, the conductor pattern including at least a conductor layer where the semiconductor device is mounted, and on a front surface of the conductor layer, the front surface of the insulating substrate, together with a periphery edge of the conductor layer, is covered by an insulating film so as to expose a mounting region where the semiconductor device is mounted.

According to the present invention, on the front surface of the conductor layer formed on the insulating substrate, the front surface of the insulating substrate, together with the periphery edge of the conductor layer, is covered by the insulating film so as to expose the mounting region where the semiconductor device is mounted. In this manner, since a recessed portion and a projecting portion formed by the periphery edge of the conductor layer are covered by the insulating film, concentration of an electric field in the recessed portion and the projecting portion at the periphery edge of the conductor layer is suppressed so that discharge from the recessed portion and the projecting portion can be suppressed.

In some aspect, a device opening in a shape corresponding to a shape of an installation surface of the semiconductor device is formed in the insulating film so that the mounting region is in a shape corresponding to the shape of the installation surface of the semiconductor device.

According to this aspect, with the device opening formed in the insulating film, the mounting region is in a shape corresponding to the shape of the installation surface of the semiconductor device, and thus, a region where the conductor layer is exposed from the insulating film can be reduced. As a result, discharge from the conductor layer can be reduced.

In another aspect, a recessed portion is formed by the mounting region and the device opening, a plating layer is further formed in the mounting region so as to fill at least a portion of the recessed portion, and a thickness of the plating layer is equal to or smaller than a depth of the recessed portion.

According to this aspect, by setting the thickness of the plating layer formed on the front surface of the conductor layer to be equal to or smaller than the depth of the recessed portion formed by the mounting region and the device opening, the periphery edge of the plating layer does not protrude from the insulating film. As a result, concentration of an electric field at the periphery edge of the plating layer is suppressed so that discharge from the periphery edge can be suppressed.

In further another aspect, a connection terminal stands on the conductor pattern, the connection terminal being electrically connected to the semiconductor device via the conductor layer, and in the insulating film, a terminal opening corresponding in shape to an end face of the connection terminal is formed at a position where the connection terminal stands, so that on the front surface of the conductor layer of the conductor pattern, a contact region exposed from the insulating film and contacting the end face of the connection terminal is formed.

According to this aspect, with the terminal opening formed in the insulating film, a contact region exposed from the insulating film and contacting the end face of the connection terminal is formed on the front surface of the conductor layer of the conductor pattern. As a result, since the periphery edge of the conductor layer where the connection terminal stands can also be covered by the insulating film, discharge from the periphery edge of the conductor layer can be suppressed.

In further another aspect, the connection terminal is a metal columnar terminal.

According to this aspect, by forming the connection terminal as a metal columnar terminal, the side surface of the connection terminal has a round shape, so that discharge from the connection terminal can be suppressed.

In further another aspect, the sealing material fills the casing from a bottom surface of the casing up to a predetermined height, and at least a columnar portion of the connection terminal present in a space in the casing beyond the predetermined height is inserted into a cylindrical insulation cylinder body made of ceramics.

According to this aspect, since the sealing material fills the casing from the bottom surface of the casing up to a predetermined height, the space in the casing beyond the predetermined height is a non-filled space filled with no sealing material. In the non-filled space, discharge from the peripheral surface of the connection terminal more easily occurs as compared to the space filled with the sealing material. Thus, according to this aspect, at least the columnar portion of the connection terminal present in the non-filled space is inserted into the insulation cylinder body made of ceramics. As a result, in the non-filled space, the columnar portion can be covered by the insulation cylinder body so that the discharge from the columnar portion of the connection terminal can be suppressed.

In further another aspect, a plurality of device mounting substrates is arranged together in the casing, each device mounting substrate having, as one set, the insulating substrate and the semiconductor device mounted on the insulating substrate, the plurality of device mounting substrates being electrically connected in series.

According to this aspect, with the plurality of device mounting substrates electrically connected in series, discharge easily occurs from the periphery edge of the conductor layer due to a high voltage, but the discharge can be effectively suppressed with the aforementioned insulating film.

According to the present invention, discharge from the conductor layer formed on the front surface of the insulating substrate can be suppressed.

### BRIEF DESCRIPTION OF THE DRAWINGS

FIG. 1 is a schematic perspective view of a power module according to an embodiment of the present invention;

FIG. 2A is a top view of the power module shown in FIG. 1, and FIG. 2B is a bottom view of the power module shown in FIG. 1;

FIG. 3 is a side view of the power module shown in FIG. 1;

FIG. 4 is a perspective view of a substrate structure shown in FIG. 1;

FIG. 5 is an exploded perspective view of the substrate structure shown in FIG. 1;

FIG. 6A is a perspective view of a connection terminal for reference voltage, FIG. 6B is an exploded perspective view of FIG. 6A, FIG. 6C is a cross-sectional view of a component mounting substrate with the connection terminal for reference voltage attached, and FIG. 6D is a cross-sectional view of a connector substrate with the connection terminal for reference voltage attached;

FIG. 7A is a schematic perspective view of an insulating substrate on which a conductor pattern is formed and an insulating film, and FIG. 7B is an exploded perspective view of a device mounting substrate;

FIG. 8A is a schematic cross-sectional view for explaining a state in which the insulating substrate on which the conductor pattern is formed is covered by the insulating film, and FIG. 8B is a modification of FIG. 8A; and

FIG. 9 is an exploded perspective view of the substrate structure shown in FIG. 5 as viewed from another side.

### DETAILED DESCRIPTION OF THE PREFERRED EMBODIMENTS

### 1. 1. Overall Structure of Power Module 1

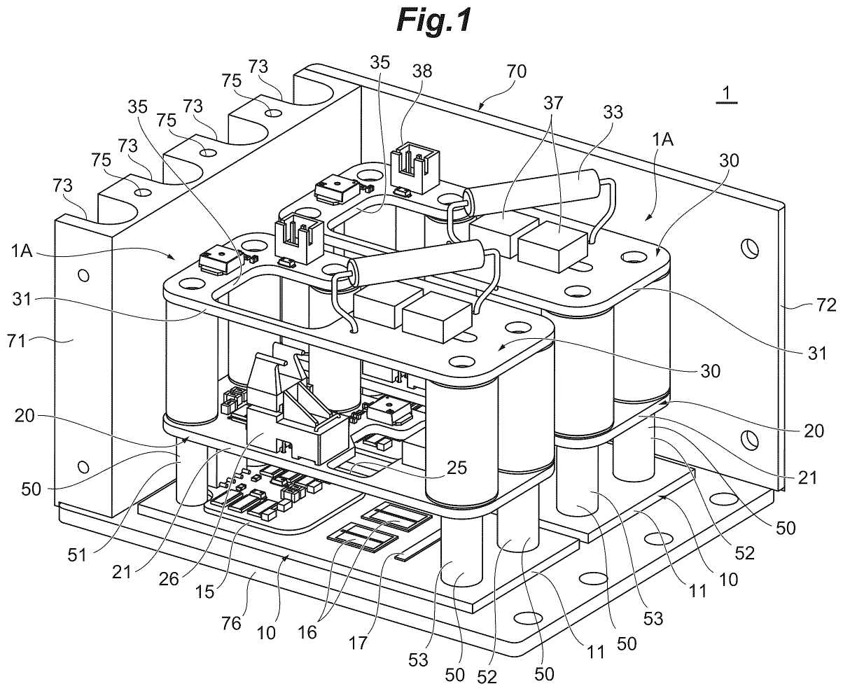

Hereinafter, with reference to FIG. 1 to FIG. 9, a power module 1 according to an embodiment of the present invention will be described. The power module 1 according to the present embodiment is a high-voltage power module (for example, with an absolute value at several kV to several ten kV). The power module 1 is, for example, a module including a semiconductor switching device, such as a high-voltage FET (field-effect transistor), and has an excellent property of dissipating heat generated by switching or the like and a structure of suppressing discharge that easily occurs when a high voltage is applied to the semiconductor switching device. Note that the present embodiment illustrates an FET module as described above as an example of the power module 1, but the power module 1 may be a diode module including a high-voltage diode (semiconductor device). The diode module can also improve the property of dissipating heat generated in the diode and suppress discharge that easily occurs when a high voltage is applied to the diode, by adopting a structure corresponding to the diode module among the structures shown below.

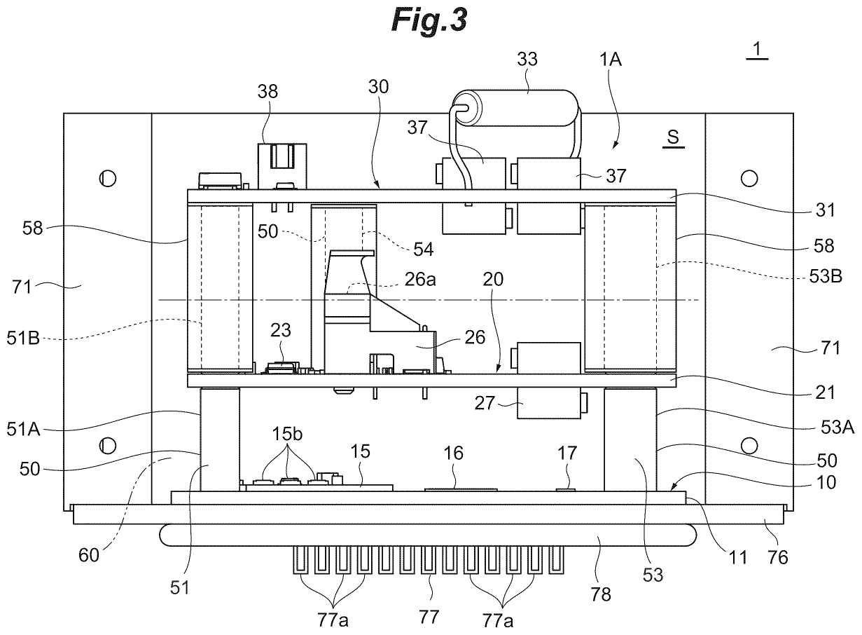

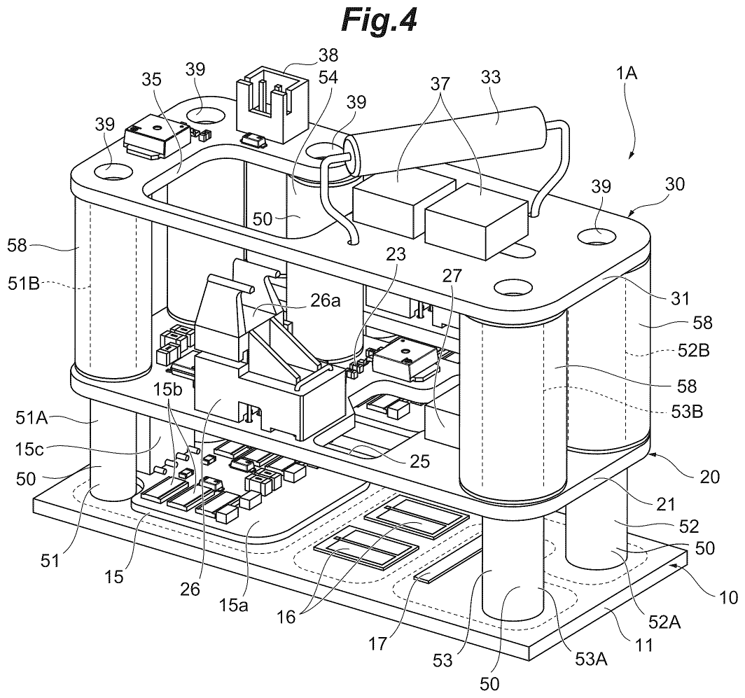

As shown in FIG. 1, the power module 1 includes a plurality (for example, two) of substrate structures 1A and a casing 70 that houses these substrate structures. As shown in FIG. 3 and FIG. 4, the substrate structure 1A includes a device mounting substrate 10, a component mounting substrate 20, and a connector substrate 30. The device mounting substrate 10 is, for example, a substrate in which at least a semiconductor device 16 is mounted on an insulating substrate 11 made of ceramics, such as an aluminum nitride and an aluminum oxide. In the present embodiment, the semiconductor device 16 is a semiconductor switching device, such as an FET (field-effect transistor) or a MOSFET (metal oxide semiconductor field-effect transistor). In the present specification, the FET and the MOSFET are collectively represented as a “field-effect transistor.” The power module 1 is an intelligent power module (IPM) with a built-in gate drive circuit 23 described later.

The component mounting substrate 20 is a substrate on which components to be mounted are mounted. The components to be mounted include an electrical component and an electronic component. Examples of the electrical component may include a passive element, such as a capacitor 27 electrically connected to the semiconductor device 16. Examples of the electronic component may include an active element, such as a transistor forming the gate drive circuit 23. The component mounting substrate 20 includes a printed circuit board 21 and the mounted components are attached to the printed circuit board 21. In the present embodiment, the electrical component and the electronic component are mounted on the component mounting substrate 20, but when the power module 1 is a diode module, only the electrical component may be mounted. Further, in the present embodiment, the capacitor 27 is mounted as the electrical component, but a resistor may be mounted as the passive element and it is only necessary that either the electrical component or the electronic component is mounted. Furthermore, one component mounting substrate 20 is disposed between the device mounting substrate 10 and the connector substrate 30, but a plurality of component mounting substrates 20 may be disposed so as to face each other between the device mounting substrate 10 and the connector substrate 30.

The connector substrate 30 is a substrate electrically connected to the mounted component on the component mounting substrate 20. The connector substrate 30 includes a printed circuit board 31 as a substrate main body. The connector substrate 30 includes a connector plug 38 to which a predetermined voltage is applied, as a connecting portion electrically connected to external equipment. Further, the connector substrate 30 includes connecting portions 53a, 54a that are connected to an adjacent substrate structure 1A or the like. A lead resistor 33 and a capacitor 37 are mounted on the connector substrate 30.

The device mounting substrate 10, the component mounting substrate 20, and the connector substrate 30 are housed in the casing 70. The device mounting substrate 10, the component mounting substrate 20, and the connector substrate 30 are coupled together by means of a plurality of metal supports 50 so as to face with a distance from each other. More specifically, the device mounting substrate 10, the component mounting substrate 20, and the connector substrate 30 are detachably coupled together, in this order from a bottom portion of the casing 70, so as to be spaced apart from each other by means of the plurality of supports 50. That is, the supports 50 each function as a spacer between the substrates. The casing 70 further houses a sealing material 60 that seals at least the device mounting substrate 10 and the component mounting substrate 20 (see FIG. 3). The sealing material 60 may entirely fill an interior of the casing 70, but in the present embodiment, the sealing material 60 fills the casing 70 from its bottom surface up to a predetermined height (see an alternate long and short dash line of FIG. 3). Specifically, the sealing material 60 fills the casing 70 up to a height (predetermined height) at which a light receiving surface 26a receiving optical fibers (not shown) of a light receiver 26 described later is not covered by the sealing material 60. In this manner, since the sealing material 60 fills the casing 70 from the bottom surface of the casing 70 up to the predetermined height, a space beyond the predetermined height in the casing 70 is a non-filled space S that is not filled with the sealing material.

In the present embodiment, the device mounting substrate 10, the component mounting substrate 20, and the connector substrate 30 are housed in the casing 70. With such a housed state, the device mounting substrate 10 and the component mounting substrate 20 face each other, and the component mounting substrate 20 and the connector substrate 30 face each other. The casing 70 includes a pair of first side walls 71, 71 facing each other and panel-like second side walls 72, 72 that are coupled to the first side walls 71, 71 on the opposite sides. The first side wall 71 and the second side wall 72 are made of resin material. The casing 70 is provided with a heat dissipating plate 76 of a copper plate or the like, as a bottom wall of the casing 70. The heat dissipating plate 76 contacts the insulating substrate 11 of the device mounting substrate 10. The heat dissipating plate 76 is fixed to the first side walls 71 and the second side walls 72, using a fixture (not shown) or the like, and in this manner, the casing 70 is formed as a housing with an upper portion opened.

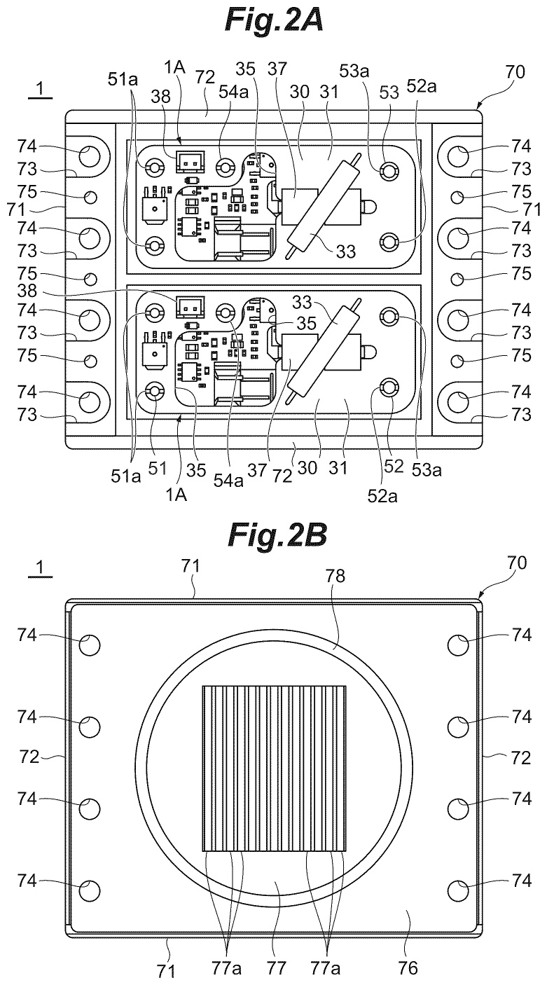

As shown in FIG. 2A, a plurality of recessed grooves 73 is formed with a distance on an outer side along a width direction of the first side wall 71. The recessed grooves 73 each extend along a depth direction of the casing 70. In this manner, projections along a depth direction of the casing 70 are formed on an outer surface of the first side walls 71, 71 and these projections function as a heat radiation fin. Further, at positions facing end portions (lower end portions) of the recessed grooves 73 on the heat dissipating plate 76, attachment holes 74 for attaching the casing 70 (heat dissipating plate 76) are formed. In this manner, a tool (not shown) such as a screwdriver is inserted along the recessed groove 73 so as to engage the fixture (not shown) inserted into the attachment hole 74, so that the casing 70 can be easily attached by means of the fixture to an external support body (not shown) or the like using the tool.

Further, as shown in FIG. 2B, a heat sink 77 is provided at a center on a back surface of the heat dissipating plate 76. The heat sink 77 includes a plurality of metal heat radiation fins 77a projecting from the back surface of the heat dissipating plate 76. An O-ring 78 is disposed around the heat sink 77 so as to surround the plurality of heat radiation fins 77a of the heat sink 77. By bringing the heat sink 77 into contact with cooling water, the heat from the heat dissipating plate 76 can be absorbed. With the O-ring 78, leakage of the cooling water can be prevented.

### 2. 2. Assembly Structure of Substrate Structure 1A

As described above, in the present embodiment, as shown in FIG. 1 and FIG. 4, the device mounting substrate 10, the component mounting substrate 20, and the connector substrate 30 are detachably coupled together, in this order from the bottom portion of the casing 70, so as to be spaced apart from each other by means of the plurality of supports 50. The supports 50 function as connection terminals 51 to 54. The connection terminals 51 to 54 are electrically connected to the mounted components, such as components of the connector plug 38, the capacitor 27, and the gate drive circuit 23, the semiconductor device 16, and the like. In the present embodiment, the connection terminals 51 to 54 are composed of the connection terminal 51 for reference voltage, the connection terminal 52 for drain, the connection terminal 53 for source, and the connection terminal 54 for drive voltage.

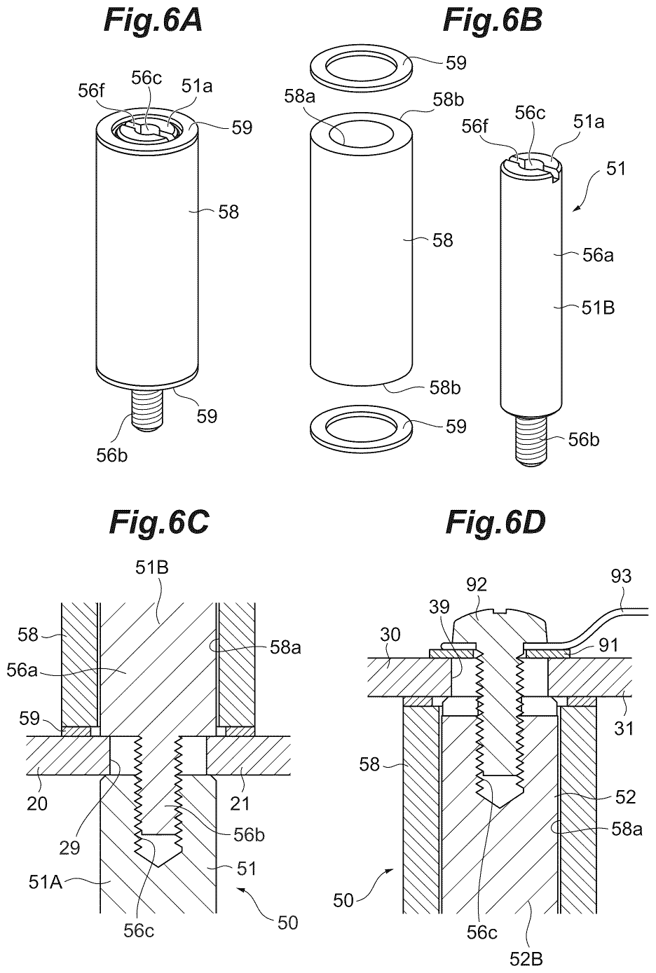

Here, the device mounting substrate 10, the component mounting substrate 20, and the connector substrate 30 are in a rectangular shape in a plan view. The two connection terminals 51 for reference voltage, the connection terminal 52 for drain, and the connection terminal 53 for source stand at four corners on the device mounting substrate 10. The connection terminals 51 to 53 are inserted into through-holes 29 formed at four corners on the component mounting substrate 20. Connecting portions 51a to 53a that are end portions (upper end portions) of the connection terminals 51 to 53 are disposed so as to be housed within through-holes 39 formed at four corners on the connector substrate 30 in a plan view of the connector substrate 30. Therefore, the end portions of the connection terminals 51 to 53 are exposed from the connector substrate 30 in the through-holes 39 in the plan view of the connector substrate 30. In this manner, as will be described later, by screwing fixtures (not shown) such as screws into internal thread portions 56c formed at end portions of the connection terminals 51 to 53, the end portions of the connection terminals 51 to 53 can function as connecting portions for mechanical connection (see, for example, FIG. 6D). Thus, by sandwiching the connector substrate 30 between the fixtures and the connection terminals 51 to 53, the connector substrate 30 can be fixed at the connection terminals 51 to 53 with the fixtures. In addition, of the end portions of the connection terminals 51 to 53, the end portions of the connection terminal 52 for drain and the connection terminal 53 for source can function as the connecting portions electrically connected to the adjacent substrate structure 1A, external equipment, or the like via wiring 93.

As long as the connection terminals 51 to 53 can support the connector substrate 30 and the connecting portions 51a to 53a thereof are housed in the through-holes 39 formed at the four corners on the connector substrate 30 in a plan view of the connector substrate 30, the positions of the end portions (connecting portions 51a to 53a) of the connection terminals 51 to 53 are not particularly limited. For example, in the present embodiment, the end portions of the connection terminals 51 to 53 contact lower side periphery edges of the through-holes 39 of the connector substrate 30. Therefore, the connecting portions 51a to 53a of the connection terminals 51 to 53 are disposed facing the through-holes 39. In addition to this, the end portions of the connection terminals 51 to 53 may be positioned inside the through-holes 39 of the connector substrate 30. Further, the end portions of the connection terminals 51 to 53 may project from the through-holes 39 of the connector substrate 30 by inserting the connection terminals 51 to 53 through the through-holes 39.

Further, in the component mounting substrate 20, the support 50 supporting the connector substrate 30 stands between the connection terminal 51 for reference voltage and the connection terminal 52 for drain along the longitudinal direction of the component mounting substrate 20. This support 50 is the connection terminal 54 for drive voltage into which a gate drive voltage for driving the gate drive circuit 23 is input. Therefore, the connection terminal 54 for drive voltage stands at a position adjacent to the gate drive circuit 23 so as to support the connector substrate 30. An end portion of the connection terminal 54 for drive voltage is disposed so as to be housed within the through-hole 39 in the plan view of the connector substrate 30. The end portion of the connection terminal 54 for drive voltage is a connecting portion 54a mechanically connected to a fixture (not shown) such as a screw, and the position thereof is the same as those of the end portions of the connection terminals 51 to 53, and thus, the detailed description will be omitted. By forming the support 50 as the connection terminals 51 to 54 electrically connected to the mounted components or the semiconductor device 16, the structure of the power module can be simplified.

The connection terminals 51 to 53 as the supports 50 are metal columnar terminals. The connection terminals 51 to 53 include first supporting posts 51A to 53A and second supporting posts 51B to 53B. The first supporting posts 51A to 53A stand on the device mounting substrate 10 and support the component mounting substrate 20. The second supporting posts 51B to 53B stand on the component mounting substrate 20 and support the connector substrate 30.

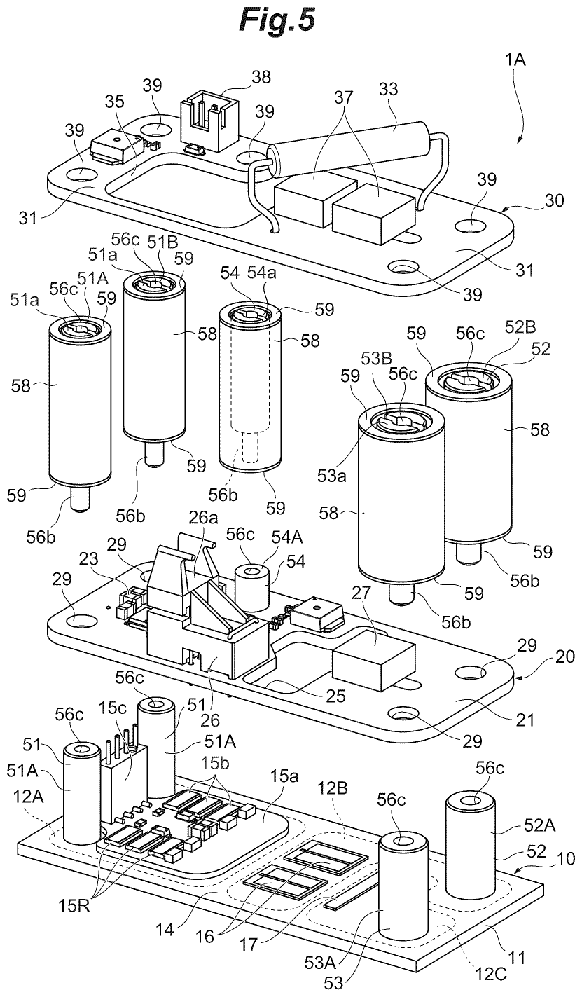

As shown in FIG. 5, in the first supporting posts 51A to 53A, internal thread portions 56c are formed in the end portions (upper end portions). In end portions (lower end portions) of the second supporting posts 51B to 53B, external thread portions 56b to be screwed into the internal thread portions 56c are formed. Note that as shown in FIG. 6B, the external thread portion 56b is a portion projecting from a columnar supporting post main body 56a. In the present embodiment, as shown in FIG. 6C, the external thread portion 56b and the internal thread portion 56c are screwed together via the through-hole 29 formed in the component mounting substrate 20. With such a screwed state, the component mounting substrate 20 is held at its four corners by means of the first supporting posts 51A to 53A and the second supporting posts 51B to 53B. Similarly, the connection terminal 54 for drive voltage includes a first supporting post 54A with the internal thread portion 56c formed therein and a second supporting post 54B with the external thread portion 56b formed therein, and the external thread portion 56b and the internal thread portion 56c are screwed together. In the present embodiment, the internal thread portions 56c are formed in the first supporting posts 51A to 54A and the external thread portions 56b are formed in the second supporting posts 51B to 54B, and the internal thread portions 56c and the external thread portions 56b are screwed together. However, as long as the internal thread portions 56c and the external thread portions 56b can be screwed together, the external thread portions 56b may be formed in the first supporting posts 51A to 54A and the internal thread portions 56c may be formed in the second supporting posts 51B to 54B.

In the present embodiment, as described above, the sealing material 60 fills the casing 70 from the bottom surface of the casing 70 up to a predetermined height. The space beyond the predetermined height in the casing 70 is the non-filled space S that is not filled with the sealing material 60 (see FIG. 3). In the present embodiment, at least the columnar portions of the connection terminals 51 to 54 present in the non-filled space S are inserted into the cylindrical insulation cylinder bodies 58 made of ceramics. Specifically, as shown in FIG. 4, FIG. 5, and FIGS. 6A, 6B, in the present embodiment, the entire columnar supporting post main bodies 56a of the second supporting posts 51B to 53B and the entire columnar portion of the connection terminal 54 for drive voltage are covered by the insulation cylinder bodies 58. Note that only the portion present in the non-filled space S may be covered by the insulation cylinder body.

Discharge more easily occurs from a peripheral surface of the connection terminal present in the non-filled space S as compared to the peripheral surface covered by the sealing material 60. In the present embodiment, the columnar portions (supporting post main bodies 56a) present in the non-filled space S of the connection terminals 51 to 54 are inserted into the insulation cylinder bodies 58 made of ceramics so that the columnar portions can be coved by the insulation cylinder bodies 58. As a result, the discharge from the columnar portions can be suppressed. Further, in the present embodiment, as shown in FIG. 6C, an O-ring 59 is disposed at an end face of the insulation cylinder body 58. By securely fitting the external thread portion 56b into the internal thread portion 56c, the O-ring 59 is deformed so that inflow of an uncured sealing material 60A, which will be described later, to an interior 58a of the insulation cylinder body 58 can be suppressed.

As shown in FIG. 2A and FIG. 5, the connecting portions 51a to 54a as the end portions (upper end portions) of the connection terminals 51 to 54 are disposed so as to be housed within the respective through-holes 39 in the plan view of the connector substrate 30. Therefore, the connecting portions 51a to 54a of the connection terminals 51 to 54 are exposed at the through-holes 39 from the connector substrate 30 in the plan view of the connector substrate 30. The internal thread portions 56c are formed in the connecting portions 51a to 54a. Of the connection terminals 51 to 53, for the connection terminal 52 for drain or the connection terminal 53 for source, as shown in FIG. 6D, a fixture 92 such as a screw inserted through the through-hole 39 is screwed into the internal thread portion 56c and wiring 93 is fixed via a washer 91. In this manner, the wiring 93 from a power source, the adjacent substrate structure 1A, or the like can be connected to the connecting portion 52a, 53a of the connection terminal 52 for drain or the connection terminal 53 for source shown in FIG. 2A. In addition, by securely fitting the fixtures 92 by screwing into the internal thread portions 56c formed in the connecting portions 51a to 54a of the connection terminals 51 to 54, the connector substrate 30 can be stably fixed in a state of being supported by the connection terminals 51 to 54. Note that in the upper end faces (connecting portions 51a to 54a) of the second supporting posts 51B to 54B, groove portions 56f for securely fitting, where a tip end of a flat-blade screwdriver (not shown) engages, are formed across the internal thread portions 56c (see, for example, FIG. 6A). As a result, the second supporting posts 51B to 54B can be easily attached to the first supporting posts 51A to 54A using the flat-blade screwdriver.

According to the present embodiment, the device mounting substrate 10, the component mounting substrate 20, and the connector substrate 30 are detachably coupled in this order from the bottom portion of the casing 70, spaced apart from each other by means of the plurality of supports 50. Thus, the device mounting substrate 10, the component mounting substrate 20, and the connector substrate 30 can be easily separated. In particular, at the time of inspection, when the electrical components such as the lead resistor 33 and the capacitors 27, 37 mounted on the component mounting substrate 20 or the connector substrate 30 do not have desired properties, the component mounting substrate 20 or the connector substrate 30 can be easily replaced.

Further, with a state in which the component mounting substrate 20 is sandwiched between the first supporting posts 51A to 53A and the second supporting posts 51B to 53B, the external thread portions 56b and the internal thread portions 56c are screwed together via the through-holes 29 formed in the component mounting substrate 20. By unscrewing the first supporting posts 51A to 53A and the second supporting posts 51B to 53B, the component mounting substrate 20 can be easily removed from between the device mounting substrate 10 and the connector substrate 30. Further, by screwing the external thread portions 56b and the internal thread portions 56c together via the through-holes 29 formed in the component mounting substrate 20, thereby securely fitting the second supporting posts 51B to 53B into the first supporting posts 51A to 53A, the component mounting substrate 20 can be stably fixed to the device mounting substrate 10 and the connector substrate 30.

Further, according to the present embodiment, the heat generated from the semiconductor device 16 mounted on the device mounting substrate 10 is easily released from the heat dissipating plate 76 contacting the insulating substrate 11. Meanwhile, the heat generated from the mounted components (for example, electronic components of the gate drive circuit 23, the capacitor 27) mounted on the component mounting substrate 20 and from the lead resistor 33 and the capacitor 37 on the connector substrate 30 conducts through the metal supports 50 via the substrates to be easily released to the outside.

Furthermore, since the device mounting substrate 10, the component mounting substrate 20, and the connector substrate 30 are disposed facing each other so as to be spaced apart from each other, the heat generated from the mounted components such as the semiconductor device 16 and a gate resistor 15R described later is also released between the substrates. The released heat is also released to the outside from the metal supports 50 via the sealing material 60. Therefore, even when the sealing material 60 is contained inside the casing 70, the heat inputted into the sealing material 60 is unlikely to be accumulated in the sealing material 60 as sensible heat and can be released to the outside from the metal supports 50. In this manner, the heat generated in the device mounting substrate 10, the component mounting substrate 20, and the connector substrate 30 can be efficiently released.

Here, the supports 50 are the connection terminals 51 to 54 that are electrically connected to the semiconductor device 16, the aforementioned mounted components, and the like. Therefore, the heat generated from the semiconductor device 16 and the mounted components is easily transmitted to the connection terminals 51 to 54 via electrically-connected paths (not shown) of these components. As a result, the heat generated from the semiconductor device 16 and the mounted components is easily released to the outside (upper side of the casing 70) from the device mounting substrate 10 side toward the connector substrate 30 side via the connection terminals 51 to 54.

In particular, the connection terminals 51 to 53 that stand at the four corners on the device mounting substrate 10 are inserted into the through-holes 29 at the four corners on the component mounting substrate 20 and are further exposed from the connector substrate 30 at the through-holes 39 at its four corners in the plan view of the connector substrate 30. Therefore, the heat generated from the semiconductor device 16 and the aforementioned mounted components is dispersed and transmitted in a balanced manner to the connection terminals 51 to 53 positioned at these four corners, so that the heat can be efficiently released to the outside from the through-holes 39 of the connector substrate 30. In particular, in terms of function, one connection terminal 51 for reference voltage may be provided, but with a plurality of connection terminals 51 for reference voltage (two in the present embodiment) provided, the heat generated in the integrated circuit such as the gate drive circuit 23 of the component mounting substrate 20 can be efficiently released from the plurality (two) of connection terminals 51 for reference voltage.

### 3. 3. Structure of Device Mounting Substrate 10 and Circuit Configuration of Power Module 1

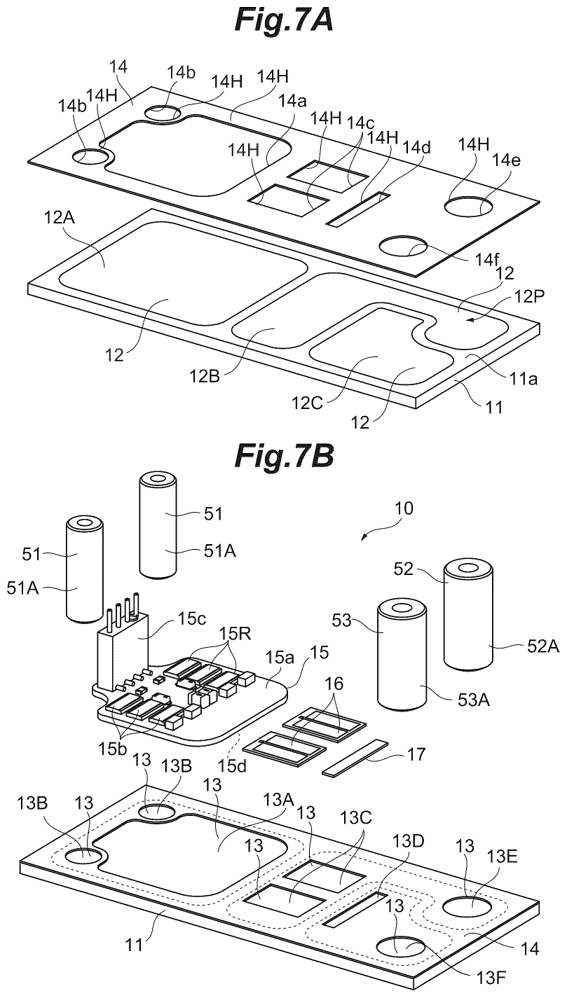

Hereinafter, the structure of the device mounting substrate 10 and a circuit configuration of the power module 1 will be described by further referring to FIG. 7 to FIG. 9. As shown in FIG. 7A, on the front surface of the insulating substrate 11, a conductor pattern 12P including at least a conductor layer 12 where the semiconductor device 16 is mounted is formed. The conductor layer 12 has a round projecting corner portion or a recessed corner portion in a plan view for suppressing the discharge. In the present embodiment, the conductor pattern 12P is formed of, for example, metal foil such as copper foil. The conductor pattern 12P includes planer first to third conductor layers 12A to 12C as the conductor layer 12. On a front surface of the second conductor layer 12B, the front surface of the insulating substrate 11, together with a periphery edge of the second conductor layer 12B, is covered by an insulating film 14 so as to expose a mounting region 13C where the semiconductor device 16 is mounted. Specifically, a device opening 14c (opening 14H) in a shape corresponding to a shape of an installation surface of the semiconductor device 16 is formed in the insulating film 14, so that the mounting region 13C (13) is in a shape corresponding to the shape of the installation surface of the semiconductor device 16. With the semiconductor device 16 installed in the mounting region 13C, the semiconductor device 16 is soldered to the second conductor layer 12B in the mounting region 13C by reflow or the like.

The semiconductor device 16 is a field-effect transistor and as described above, the component mounting substrate 20 is provided with the gate drive circuit 23, which is an electronic circuit composed of a mounted component such as an electronic component and is adapted to drive the semiconductor device 16 as the field-effect transistor. Voltage from the connection terminal 54 for drive voltage is input to the gate drive circuit 23. Further, the gate drive circuit 23 controls the waveform of the gate drive voltage, using a light signal (pulse signal) received at the light receiver 26 as a control signal and generates a pulse signal composed of a PWM signal. In the present embodiment, on one side of opposite sides across an inlet 25 in the component mounting substrate 20, the light receiver 26 and the gate drive circuit 23 are arranged together. In this manner, with the gate drive circuit 23 and the light receiver 26 arranged together on one side of the opposite sides across the inlet 25, the light receiver 26 can be disposed near the gate drive circuit 23. Therefore, the light signal received at the light receiver 26 can be accurately input into the gate drive circuit 23. Thus, the pulse waveform of the gate drive voltage that drives (switches) the semiconductor device (field-effect transistor) 16 can be accurately generated at the gate drive circuit 23.

On the device mounting substrate 10, an interposer (relay substrate) 15, which connects, as a relay, the gate drive circuit 23 and the semiconductor device (field-effect transistor) 16, and a relay component 17 are mounted and these are electrically connected using a wire (not shown) by wire bonding or the like. The interposer 15 includes a wiring board 15a, and the wiring board 15a is provided with the gate resistor 15R composed of a chip resistor 15b. Further, the wiring board 15a is also provided with a gate-source resistor. The gate drive circuit 23 is electrically connected to a terminal of a connector 15c mounted on the wiring board 15a.

In the present embodiment, a conductor layer 15d made of copper is formed on a back surface of the interposer 15, and a front surface of the conductor layer 15d is further covered with solder. On a front surface of the first conductor layer 12A, the front surface of the insulating substrate 11, together with a periphery edge of the first conductor layer 12A, is covered by the insulating film 14 so as to expose a mounting region 13A where the interposer 15 is mounted. Specifically, an interposer opening 14a (opening 14H) in a shape corresponding to a shape of an installation surface of the interposer 15 is formed in the insulating film 14, so that the mounting region 13A (13) is in a shape corresponding to the shape of the installation surface of the interposer 15. With the interposer 15 installed in the mounting region 13A, the interposer 15 is soldered to the first conductor layer 12A in the mounting region 13A by reflow or the like.

On the front surface of the second conductor layer 12B, a mounting region 13D where the relay component 17 is mounted is formed. Likewise, for the relay component 17, a component opening 14d (opening 14H) is formed so that a mounting region 13D (13) is in a shape corresponding to a shape of an installation surface of the relay component 17. With the relay component 17 installed in the mounting region 13D, the relay component 17 is soldered to the third conductor layer 12C in the mounting region 13D by reflow or the like.

Further, the aforementioned connection terminals 51 to 53 stand on the conductor pattern 12P so that the conductor pattern 12P is directly or indirectly electrically connected to the semiconductor device 16 or the like via the first to third conductor layers 12A to 12C (conductor layer 12). In the insulating film 14, terminal openings 14b, 14e, 14f corresponding in shape to the end faces of the connection terminals are formed at positions where the connection terminals 51 to 53 stand. In this manner, on the front surfaces of the first to third conductor layers 12A to 12C (conductor layer 12) of the conductor pattern 12P, contact regions 13B, 13E, 13F exposed from the insulating film 14 and contacting the end faces of the connection terminals 51 to 53 are formed. The connection terminals 51 to 53 are soldered to the corresponding first to third conductor layers 12A to 12C in the respective contact regions 13B, 13E, 13F. Since the connection terminals 51 to 53 are metal columnar terminals and thus have round side surfaces, the discharge from the connection terminals 51 to 53 can be suppressed. In the present embodiment, the connection terminals 51 to 53 are columnar terminals, but the connection terminals 51 to 53 may be, for example, terminals in a polygonal columnar shape with round corners (edge lines).

Here, in the connector substrate 30, voltage supplied to the connector plug 38 from external equipment is converted into reference voltage and gate drive voltage. The converted reference voltage is supplied to the connection terminal 51 for reference voltage and is input to the first conductor layer 12A via the connection terminal 51 for reference voltage. Therefore, the first conductor layer 12A servers as a conductor layer for reference voltage. Meanwhile, the gate drive voltage is supplied to the connection terminal 54 for drive voltage and is input to the gate drive circuit 23. From the gate drive voltage and the aforementioned light signal (PWM signal), the gate drive circuit 23 generates the gate drive voltage having a pulse waveform. Here, with the reference voltage input to the first conductor layer 12A, the potential of the gate drive voltage generated in the gate drive circuit 23 is adjusted to an appropriate potential. Such a gate drive voltage is applied between the gate and the source of the semiconductor device 16 as a gate drive signal.

Further, of the connection terminals 51 to 53, the connection terminal 52 for drain is a terminal connected to a drain terminal (not shown) of the semiconductor device (field-effect transistor) 16. The second conductor layer 12B is a conductor layer for drain that is electrically connected to the drain terminal of the semiconductor device (field-effect transistor) 16. Furthermore, of the connection terminals 51 to 53, the connection terminal 53 for source is a terminal connected to a source terminal (not shown) of the semiconductor device (field-effect transistor) 16. The third conductor layer 12C is a conductor layer for source that is electrically connected to the source terminal of the semiconductor device (field-effect transistor) 16. On the second conductor layer (conductor layer for drain) 12B, the connection terminal 52 for drain stands. On the third conductor layer (conductor layer for source) 12C, the connection terminal 53 for source stands.

In this manner, the heat generated in the semiconductor device (field-effect transistor) 16 is transmitted to the heat dissipating plate 76 via the insulating substrate 11 from the second conductor layer (conductor layer for drain) 12B and the third conductor layer (conductor layer for source) 12C that are electrically connected to the source terminal and the drain terminal, and is released from the heat dissipating plate 76. Further, the heat generated in the semiconductor device (field-effect transistor) 16 can also be released from the connection terminal 53 for source and the connection terminal 52 for drain that stand on the third conductor layer (conductor layer for source) 12C and the second conductor layer (conductor layer for drain) 12B, respectively. Meanwhile, the gate resistor 15R mounted on the interposer 15, as well as the semiconductor device 16, also generates heat. The heat generated in the gate resistor 15R is transmitted to the heat dissipating plate 76 from the first conductor layer (conductor layer for gate resistor) 12A that is indirectly, electrically connected to the gate terminal and can be released from the heat dissipating plate 76.

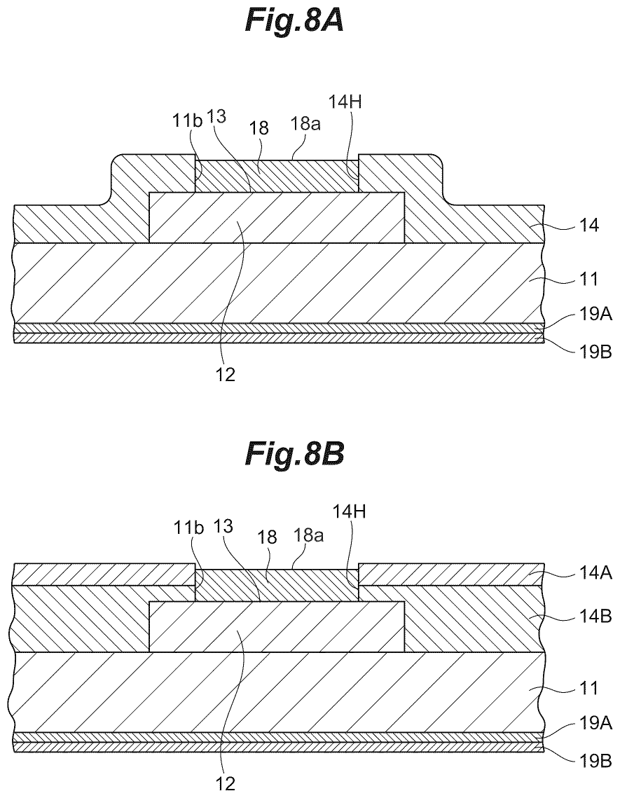

In this manner, as shown in FIG. 8A, on the front surface of the conductor layer 12 formed on the insulating substrate 11, the front surface of the insulating substrate 11, together with the periphery edge of the conductor layer 12, is covered by the insulating film 14 so as to expose the mounting region 13 where the semiconductor device 16 is mounted. Note that here, the periphery edge of the conductor layer 12 refers to the periphery edge including the front surface and the side surface of the conductor layer 12. In this manner, since a projecting portion and a recessed portion formed by the periphery edge of the conductor layer 12 and the front surface of the insulating substrate 11 are covered by the insulating film 14, the concentration of the electric field in the projecting portion and the recessed portion of the periphery edge of the conductor layer 12 can be suppressed so that the discharge from these projecting portion and recessed portion can be suppressed. From the results of analysis or the like conducted by the inventors, the mounting region 13 is preferably formed on an inner side by 5 mm or more from the periphery edge of the conductor layer 12. In this manner, the discharge near the mounting region 13 can be suppressed.

Further, with the opening 14H formed in the insulating film 14, the mounting region 13 has a shape corresponding to the shape of the installation surface of the semiconductor device 16 or the like, thereby being able to reduce a region where the conductor layer 12 is exposed from the insulating film 14. In this manner, the discharge from the conductor layer 12 can be reduced. Further, with the terminal openings 14b, 14e, 14f formed in the insulating film 14, on the front surface of the conductor layer 12 of the conductor pattern 12P, the contact regions 13B, 13E, 13F exposed from the insulating film 14 and contacting the end faces of the connection terminals 51 to 53 are formed. Thus, of the conductor layer where the connection terminals 51 to 53 stand, the periphery edges of the contact regions 13B, 13E, 13F can also be covered by the insulating film 14, and thus, the discharge from the periphery edge of the conductor layer 12 can be suppressed. From the results of analysis or the like conducted by the inventors, the contact regions 13B, 13E, 13F are preferably formed on the inner side by 5 mm or more from the periphery edge of the conductor layer 12. In this manner, the discharge near the contact regions 13B, 13E, 13F can be suppressed.

Here, the dielectric breakdown strength of the insulating film 14 is preferably higher than that of the sealing material 60, preferably 200 kV/mm or greater, for example. Examples of the material of the insulating film 14 may include a resin material such as a polyimide resin. The dielectric breakdown strength of the sealing material 60 is around 20 kV/mm, and examples of the material of the sealing material 60 may include a gel-like insulation material such as silicone gel.

Further, as shown in FIG. 8A, a recessed portion 11b is formed by the mounting region 13 and the opening 14H, and a plating layer 18 may be further formed in the mounting region 13 so as to fill at least part of the recessed portion 11b. The plating layer 18 is a layer made of boron nickel formed by electroless nickel plating, for example. In this case, a front surface 18a of the plating layer 18 serves as a mounting region where the semiconductor device 16 is mounted. In the present embodiment, the thickness of the plating layer 18 is equal to or smaller than the depth of the recessed portion 11b. Further, on a back surface of the insulating substrate 11, a conductor layer 19A and a plating layer 19B that are made of copper are formed and these layers function as an earth. Furthermore, as shown in FIG. 8B, an adhesive layer 14B having a thickness greater than that of the conductor layer 12 may be provided, and an insulating film 14A may be disposed on the adhesive layer 14B. In this manner, the insulating film 14A can be provided at the edges of the insulating substrate 11 and the conductor layer 12, with the insulating film 14A in a flat state. Note that the insulating films 14, 14A are films attached to the edges of the insulating substrate 11 and the conductor layer 12 by vacuum lamination processing.

According to this aspect, the thickness of the plating layer 18 formed on the front surface of the conductor layer 12 is equal to or smaller than the depth of the recessed portion 11b formed by the mounting region 13 and the opening 14H. Thus, the periphery edge of the plating layer 18 does not protrude from the insulating film 14. As a result, concentration of the electric field at the periphery edge of the plating layer 18 is suppressed so that the discharge from the periphery edge can be suppressed.

The power module 1 is provided with a plurality of resistors, the device mounting substrate 10 is provided with the chip resistor 15b of the plurality of resistors, and the connector substrate 30 is provided with the lead resistor 33. Note that the lead resistor 33 is connected between the connection terminal 52 for drain and the connection terminal 53 for source to stabilize the voltage therebetween, and for the same purpose, the capacitors 27, 37 are provided in the component mounting substrate 20 and the connector substrate 30, respectively. Note that the lead resistor 33 may be provided in the component mounting substrate 20.

With the resistors arranged as such, the lead resistor 33 is mounted on at least one of the component mounting substrate 20 and the connector substrate 30 that are spaced apart from the device mounting substrate 10. Therefore, the heat generated from the lead resistor 33 can be released to the outside from the connector substrate 30 side. Meanwhile, since the chip resistor 15b that generates less heat as compared to the lead resistor 33 is provided in the device mounting substrate 10, the heat can be released to the outside via the heat dissipating plate 76. In this manner, since the lead resistor 33 that generates more heat as compared to the chip resistor 15b releases the heat to the outside from the connector substrate 30 side, the heat generated from the semiconductor device 16 can be more efficiently released from the heat dissipating plate 76.

Further, the heat generated in the gate drive circuit 23 can be released from the metal support 50 (connection terminal 51 for reference voltage). Meanwhile, on the device mounting substrate 10, the interposer 15 that connects, as a relay, the gate drive circuit 23 and the semiconductor device (field-effect transistor) 16 is mounted, and the interposer 15 is provided with the gate resistor 15R composed of the chip resistor 15b. Thus, the heat generated from the gate resistor 15R can be released from the heat dissipating plate 76. In this manner, the heat generated from each of the gate drive circuit 23 and the gate resistor 15R can be dispersed.

### 4. 4. Filling of Sealing Material 60 (60A)

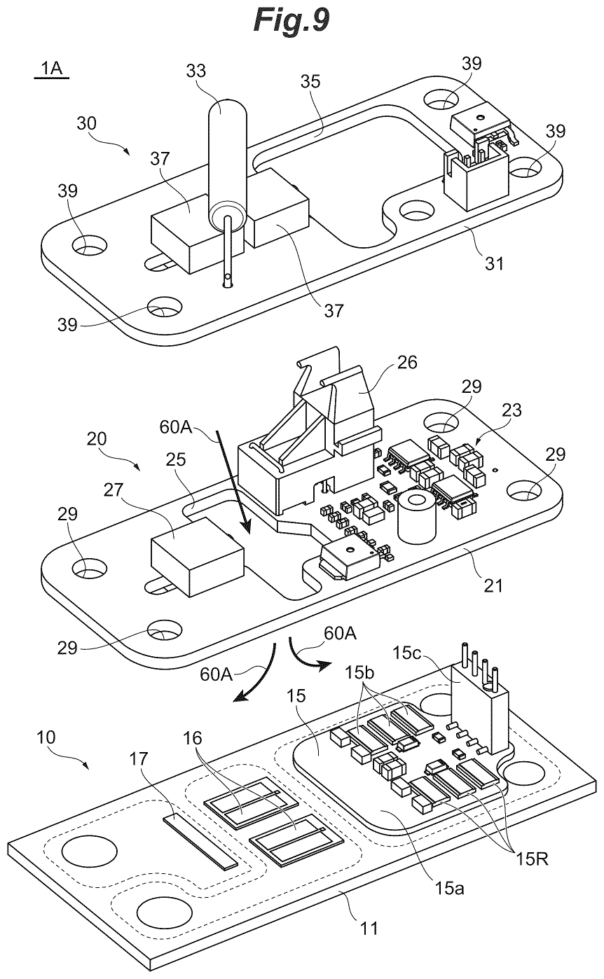

As shown in FIG. 9, the component mounting substrate 20 is in a rectangular shape, and at the center of the component mounting substrate 20, the inlet 25 for introducing the sealing material 60A that seals the device mounting substrate 10 inside the casing 70 is formed. Further, as described above, on the component mounting substrate 20, the light receiver 26 that is connected to optical fibers and that receives a light signal of the optical fibers (not shown) is mounted, as one of the mounted components. At a position facing the light receiver 26 on the connector substrate 30, an opening 35 is formed.

According to this aspect, at the center of the component mounting substrate 20, the inlet 25 for introducing the sealing material 60A that seals the device mounting substrate 10 inside the casing 70 is formed. In this manner, the uncured liquid sealing material 60A can be made to stably flow toward the device mounting substrate 10 from the inlet 25 of the component mounting substrate 20. As a result, the entire front surface of the device mounting substrate 10 can be uniformly sealed with the sealing material 60A while suppressing formation of air bubbles in the sealing material 60A.

Further, before the optical fibers are guided through the opening 35 and connected to the light receiver 26, with the use of the opening 35 of the connector substrate 30, a jig (not shown) for discharging the sealing material 60A is inserted. The sealing material 60A discharged by means of the inserted jig can be introduced from the inlet 25 of the component mounting substrate 20 toward the device mounting substrate 10. In this manner, while confirming that there is no adhesion of the sealing material 60A to the light receiving surface 26a of the light receiver 26, the device mounting substrate 10 and the component mounting substrate 20 that are positioned on a further bottom surface side of the casing relative to the light receiving surface 26a can be filled with the sealing material 60A. Thereafter, the liquid sealing material 60A is cured. After completion of sealing with the sealing material 60A, the optical fibers are guided through the opening 35 of the connector substrate 30 to the light receiver 26 so that the optical fibers can be easily connected to the light receiver 26.

### 5. 5. Arrangement and Connection of Substrate Structure 1A

In the present embodiment, inside the casing 70, a plurality (for example, two) of device mounting substrates 10, each having, as one set, the insulating substrate 11 and the semiconductor device 16 mounted on the insulating substrate 11, is arranged together and electrically connected in series to each other. Specifically, with a plurality (for example, two) of substrate structures 1A arranged together, each of which has the device mounting substrate 10, the component mounting substrate 20, and the connector substrate 30 that are coupled together via the supports 50, the connection terminal 53 for source of one of the adjacent substrate structures 1A is electrically connected to the connection terminal 52 for drain of the other of the adjacent substrate structures 1A. The connection terminal 53 for source and the connection terminal 52 for drain connected to each other are the connection terminal 53 for source and the connection terminal 52 for drain of a pair of substrate structures 1A that are adjacent to each other. Further, a plurality (for example, eight) of power modules 1 may be arranged side-by-side and the connection terminal 53 for source and the connection terminal 52 for drain of the adjacent power modules 1 may be connected.

With such a connection in series, the plurality of device mounting substrates 10 easily discharge from the periphery edges of the conductor layers 12 due to a high voltage, but the discharge can be more effectively suppressed with the aforementioned insulating film 14. In particular, since with the plurality of substrate structures 1A arranged together, the connection terminal 53 for source of one substrate structure 1A of the adjacent substrate structures 1A, 1A and the connection terminal 52 for drain of the other substrate structure 1A are electrically connected, the adjacent substrate structures 1A, 1A are connected in series so as to cause each substrate structure 1A to perform conversion from a DC voltage to an AC voltage in a high-voltage region, thereby being able to disperse the heat generated at the time of conversion to each substrate structure 1A.

The embodiment of the present invention has been described in detail above, but the present invention is not limited to the aforementioned embodiment and various design changes can be made within the range without departing from the spirit of the present invention described in the scope of claims.

What is claimed is:

1. A high voltage power module comprising:
an insulating substrate made of ceramics;
a semiconductor device mounted on the insulating substrate;
a casing that houses the insulating substrate together with the semiconductor device; and
a sealing material that seals the semiconductor device inside the casing,
wherein on a front surface of the insulating substrate, a conductor pattern is formed, the conductor pattern including at least a conductor layer where the semiconductor device is mounted, and
on a front surface of the conductor layer, the front surface of the insulating substrate, together with a periphery edge of the conductor layer, is covered by an insulating film so as to expose a mounting region where the semiconductor device is mounted.

2. The power module according to claim 1, wherein a device opening in a shape corresponding to a shape of an installation surface of the semiconductor device is formed in the insulating film so that the mounting region is in a shape corresponding to the shape of the installation surface of the semiconductor device.

3. The power module according to claim 2, wherein
a recessed portion is formed by the mounting region and the device opening,
a plating layer is further formed in the mounting region so as to fill at least a portion of the recessed portion, and
a thickness of the plating layer is equal to or smaller than a depth of the recessed portion.

4. The power module according to claim 1, wherein
a connection terminal stands on the conductor pattern, the connection terminal being electrically connected to the semiconductor device via the conductor layer, and
in the insulating film, a terminal opening corresponding in shape to an end face of the connection terminal is formed at a position where the connection terminal stands, so that on the front surface of the conductor layer of the conductor pattern, a contact region exposed from the insulating film and contacting the end face of the connection terminal is formed.

5. The power module according to claim 4, wherein the connection terminal is a metal columnar terminal.

6. The power module according to claim 5, wherein
the sealing material fills the casing from a bottom surface of the casing up to a predetermined height, and
at least a columnar portion of the connection terminal present in a space in the casing beyond the predetermined height is inserted into a cylindrical insulation cylinder body made of ceramics.

7. The power module according to claim 1, wherein a plurality of device mounting substrates is arranged together in the casing, each device mounting substrate having, as one set, the insulating substrate and the semiconductor device mounted on the insulating substrate, the plurality of device mounting substrates being electrically connected in series.
